(19) United States
(12) Patent Application Publication
(10) Pub. No.: US 2013/0088844 A1
(43) Pub. Date: Apr. 11, 2013

(54) Base of Display Device

(71) Applicants: Wei-Lu Zeng, Fuqing City (CN); Mei-Can Fang, Fuqing City (CN); Lei Wang, Fuqing City (CN)

(72) Inventors: Wei-Lu Zeng, Fuqing City (CN); Mei-Can Fang, Fuqing City (CN); Lei Wang, Fuqing City (CN)

(21) Appl. No.: 13/549,566

(22) Filed: Jul. 16, 2012

(30) Foreign Application Priority Data
Oct. 9, 2011 (CN) 201120378497.2

(51) Int. Cl. H05K 7/12

(52) U.S. Cl. 361/808

(57) ABSTRACT

The invention relates to a base of a display device, comprising a base body, a first wing connected to one side of the base body and a second wing connected to the other side of the base body. The base body comprises a pillar which supports the display device. The first wing and the second wing are hinged on base body in a swivelable manner so that the first wing and the second wing can swivel relative to the base body. Alternatively, the first wind and the second wing are detachably connected to the base body so that the first wing and the second wing can form different aspects relative to the base body. As a result, the first wing and the second wing can be adjusted relative to the base body in terms of positions and aspects according to requirements.

### BACKGROUND OF THE INVENTION

1. Field of the Invention

The present invention relates to a base and particularly to a base of a display device.

2. Description of the Related Art

A traditional cathode ray tube (CRT) display device often occupies a large amount of space. The display device equipped with a large CRT also requires a larger bearing area. Nowadays most display devices are made thinner, such as plasma display or liquid crystal display. Even the thin display device with a viewing size larger than 50 inches can be formed at a thickness smaller than that of the CRT display of 15 inches. Theoretically, slim display devices can provide great improvement over the CRT display in terms of the problem of occupying a large amount of space. But in practice the slim display devices formed at a larger size require greater resting stability. Hence the base to support the slim display also needs a greater holding area to provide sufficient support at the front side and rear side to prevent the slim display device from tilting forwards or backwards. As a result, even if the slim display device is formed thinner, the base still occupies a large amount of space. Therefore, a base of the display device that is changeable according to requirements and occupies a smaller area is in need desperately.

### SUMMARY OF THE INVENTION

The present invention aims to provide a base of a display device that is changeable in structure to reduce occupying space according to requirements.

According to the object set forth, the present invention provides the base of the display device that is positioned onto a bearing surface to support the display device. The base comprises a base body, a first wing and a second wing. The base body includes a pillar, a bottom face butting the bearing surface, and a first side face and a second side face opposite to each other and adjacent to the bottom face. The pillar has a top end connecting to the display device to provide support thereof. The first side face has a first connecting part.

The first wing has a bottom face and a side face. The side face has a second connecting part corresponding to the first connecting part. The first connecting part is hinged on the second connecting part in a swivelable manner so that the first wing can swivel against the base body between a first position and a second position. When the first wing is swivelled to the first position, the bottom face of the first wing is substantially perpendicular to the bearing surface. When the first wing is swivelled to the second position, the bottom face of the first wing and the bottom face of the base body butt the bearing surface simultaneously. Alternatively, the first connecting part is detachably connected to the second connecting part to allow the first wing to form a first aspect and a second aspect relative to the base body. At the first aspect, the first wing is integrated with the base body, and the bottom face of the first wing and the bottom face of the base body butt the bearing surface simultaneously. At the second aspect, the first wing is detached from the base body. The second wing is connected to the second side face of the base body.

The present invention provides another type of base of a display device that comprises a base body module, a first wing and a second wing. The base body module includes a first base body, a second base body, a third base body, a fourth base body and a pillar. The first base body, the second base body, the third base body and the fourth base body are hinged on the pillar in a swivelable manner and have respectively a bottom face butting the bearing surface. The pillar has a top end connecting to the display device to provide support thereof.

The first wing has a bottom face and a side face. The first base body and the second base body have respectively a side face with a first connecting part located thereon. The first wing has a side face with a second connecting part corresponding to the first connecting part. The first connecting part is detachably connected to the second connecting part to allow the first wing to form a first aspect and a second aspect relative to the base body module. At the first aspect, the first wing is integrated with the first base body and the second base body, and the bottom face of the first wing and the bottom face of the base body butt the bearing surface simultaneously. At the second aspect, the first wing is detached from the first base body and the second base body. The second wing has a bottom face and a side face. The third base body and the fourth base body have respectively a side face with a third connecting part located thereon. The side face of the second wing has a fourth connecting part corresponding to the third connecting part. The third connecting part is detachably connected to the fourth connecting part to allow the second wing to form a third aspect and a fourth aspect relative to the base body module. At the third aspect, the second wing is integrated with the third base body and the fourth base body, and the bottom face of the second wing and the bottom face of the base body butt the bearing surface simultaneously. At the fourth aspect, the second wing is detached from the third base body and the fourth base body.

At the second aspect, the first base body and the second base body are swivelable between a first position and a second position. The first base body and the second base body are adjacent to each other at the first position, meanwhile the first connecting parts on the first base body and the second base body are coupled with each other. At the fourth aspect, the third base body and the fourth base body are swivelable between a third position and a fourth position. The third base body and the fourth base body are adjacent to each other at the third position, meanwhile the third connecting parts on the third base body and the fourth base body are coupled with each other. When the first base body and the second base body are at the second position, and the third base body and the fourth base body are at the fourth position, the first base body is adjacent to the third base body, and the second base body is adjacent to the fourth base body.

The base of the display device provided by the present invention is changeable in structure according to requirements, not only can reduce occupying space, also retain the stability of supporting the display device. Compared to the prior art, the present invention has more flexibility.

### BRIEF DESCRIPTION OF THE DRAWINGS

The foregoing and other features of the disclosure will be apparent and easily understood from a further reading of the specification, claims and by reference to the accompanying drawings in which:

FIG. 1 is an exemplary diagram illustrating a first embodiment of a base of a display device of the present invention;

FIG. 2 is a three-dimensional diagram illustrating a first embodiment of a base of a display device of the present invention;

FIG. 3 is an exemplary diagram illustrating a second embodiment of a base of a display device of the present invention;

FIG. 4 is a three-dimensional diagram illustrating a second embodiment of a base of a display device of the present invention;

FIGS. 5a, 5b, 5c and 5d are top views of schematic decomposition movements illustrating a second embodiment of a base of a display device of the present invention;

FIG. 6 is a three-dimensional diagram illustrating a third embodiment of a base of a display device of the present invention;

FIGS. 7a and 7b are top views of schematic decomposition movements illustrating a third embodiment of a base of a display device of the present invention;

FIG. 8 is a schematic diagram illustrating a fourth embodiment of a base of a display device of the present invention; and

FIGS. 9a and 9b are top views of schematic decomposition movements illustrating a fifth embodiment of a base of a display device of the present invention.

### DETAILED DESCRIPTION OF THE INVENTION

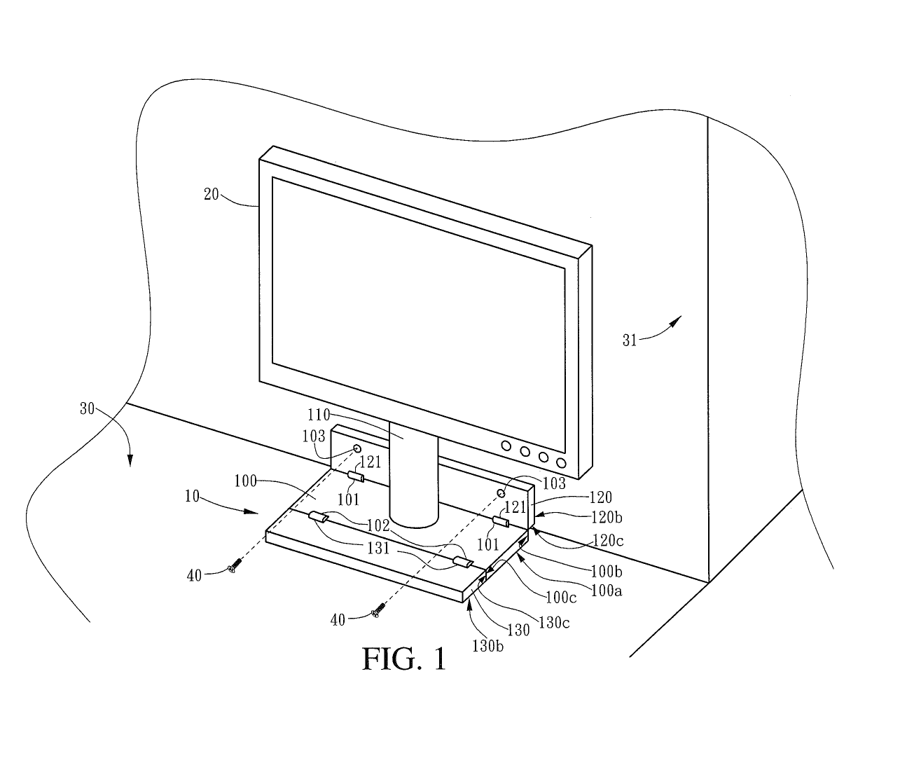

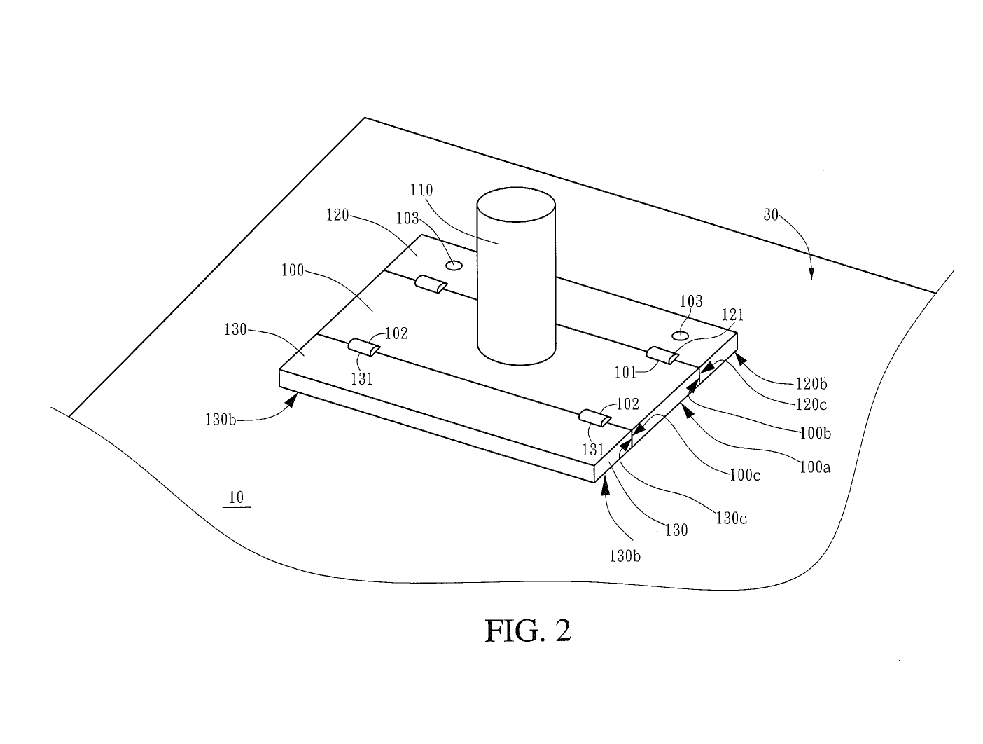

Please refer to FIG. 1 for an exemplary diagram illustrating a first embodiment of a base of a display device of the present invention, and FIG. 2 for a three-dimensional diagram illustrating the first embodiment of the invention. A base 10 includes a base body 100, a first wing 120 and a second wing 130. The base body 100 includes a pillar 110, a bottom face 100a, a first side face 100b and a second side face 100c. The pillar 110 has a top end connecting to a display device 20 to provide support thereof. The first side face 100b has a first connecting part 101 located thereon. The second side face 100c has a third connecting part 102 located thereon.

The first wing 120 has a bottom face 120b and a side face 120c. The side face 120c has a second connecting part 121 located thereon. The first connecting part 101 is hinged on the second connecting part 121 in a swivelable manner to allow the first wing 120 to swivel relative to the base body 100 between a first position and a second position. When the first wing 120 is swivelled to the first position, the bottom face 120b is substantially perpendicular to a bearing surface 30, that makes the first wing 120 attachable to a wall 31, as shown in FIG. 1. Furthermore, the first wing 120 has a through-hole 103 passed through by a coupling element 40 to fasten the first wing 120 to the wall 31 to increase stability of supporting the display device 20. The aforementioned “substantially perpendicular” means that the angle between the bottom face 120b of the first wing and the bearing surface 30 may not be 90 degrees exactly because of influence of practical environment, e.g. the wall itself could be not perpendicular to the bearing surface, or existing of fabrication tolerances.

When the first wing 120 is swivelled to the second position, the bottom face 120b of the first wing and the bottom face 100a of the base body butt the bearing surface 30 simultaneously, as shown in FIG. 2. Such kind of aspect is adapted to a situation in which the display device 20 is not close to the wall 31, and the coupling element 40 also can pass through the through-hole 103 to fasten the first wing 120 to the bearing surface 30.

The shape and size of the second wing 130 and the first wing 120 are symmetric. The second wing 130 also has a bottom face 130b and a side face 130c. The side face 130c has a fourth connecting part 131 located thereon that is hinged on third connecting part 102 in a swivelable manner to allow the second wing 130 to swivel relative to the base body 100 between a third position and a fourth position. When the second wing 130 is swivelled to the third position, the bottom face 130b of the second wing is substantially perpendicular to the bearing surface 30. Such kind of aspect is adapted to a situation that has a fixed low cabinet or an object with a wall in front of the display device 20 to provide fastening. When the second wing 130 is swivelled to the fourth position, the bottom face 130b of the second wing and the bottom face 100a of the base body butt the bearing surface 30 simultaneously. In other embodiments, the second wing could be fixed to the base body or integrated with the base body, and not swivelable.

In this embodiment, the second wing 130 does not have a through-hole. But in other embodiments, the second wing could have a through-hole, such that when the second wing is swivelled to the third position, the through-hole can be passed through by a coupling element to fasten the second wing to the wall; alternatively, when the second wing is swivelled to the fourth position, the through-hole can be passed through by a coupling element to fasten the second wing to the bearing surface. In addition, the bottom face of the base body, the bottom face of the first wing and the bottom face of the second wing could also hold respectively an anti-slip pad.

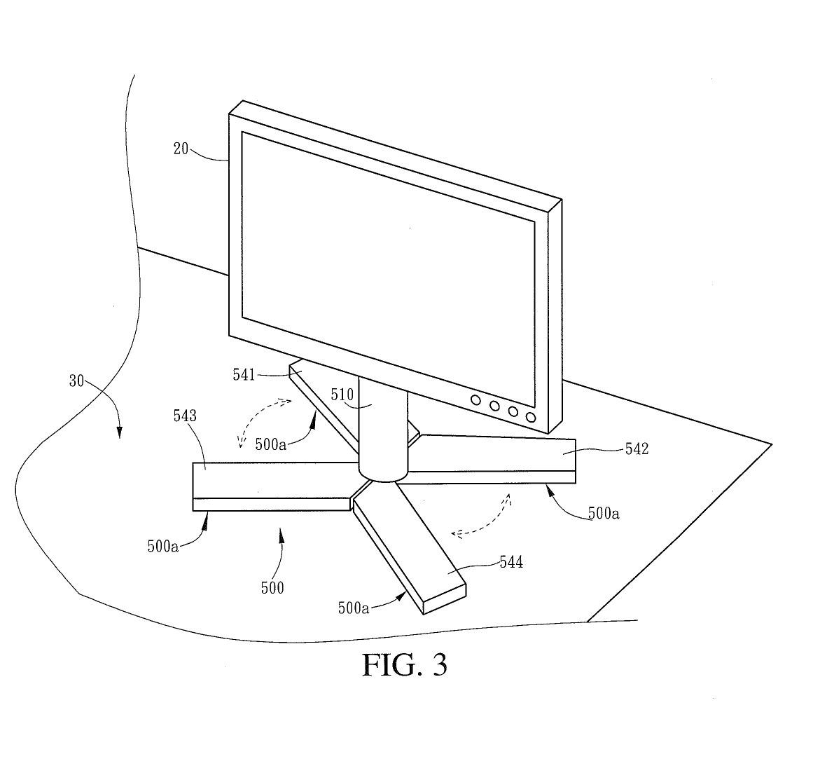

Please refer to FIGS. 3, 4, and 5a through 5d for a second embodiment of the invention. A base 50 includes a base body module 500, a first wing 520 and a second wing 530. The base body module 500 includes a first base body 541, a second base body 542, a third base body 543, a fourth base body 544 and a pillar 510. The first base body 541, the second base body 542, the third base body 543 and the fourth base body 544 are hinged on the pillar 510 and swivelable respectively about the pillar 510, and each base body has a bottom face 500a butting the bearing surface 30. The pillar 510 has a top end connecting to the display device 20 to provide support thereof. The first base body 541 and the second base body 542 have respectively a side face with a first connecting part 501 located thereon. The third base body 543 and the fourth base body 544 also have respectively a side face with a third connecting part 502 located thereon.

The first wing 520 has a bottom face 520b and a side face 520c. The side face 520c has a second connecting part 521 located thereon detachably connected to the first connecting part 501 such that the first wing 520 can form a first aspect and a second aspect relative to the base body module 500. The aforementioned sentence “detachably connected” means that the two components can be selectively connected or separated.

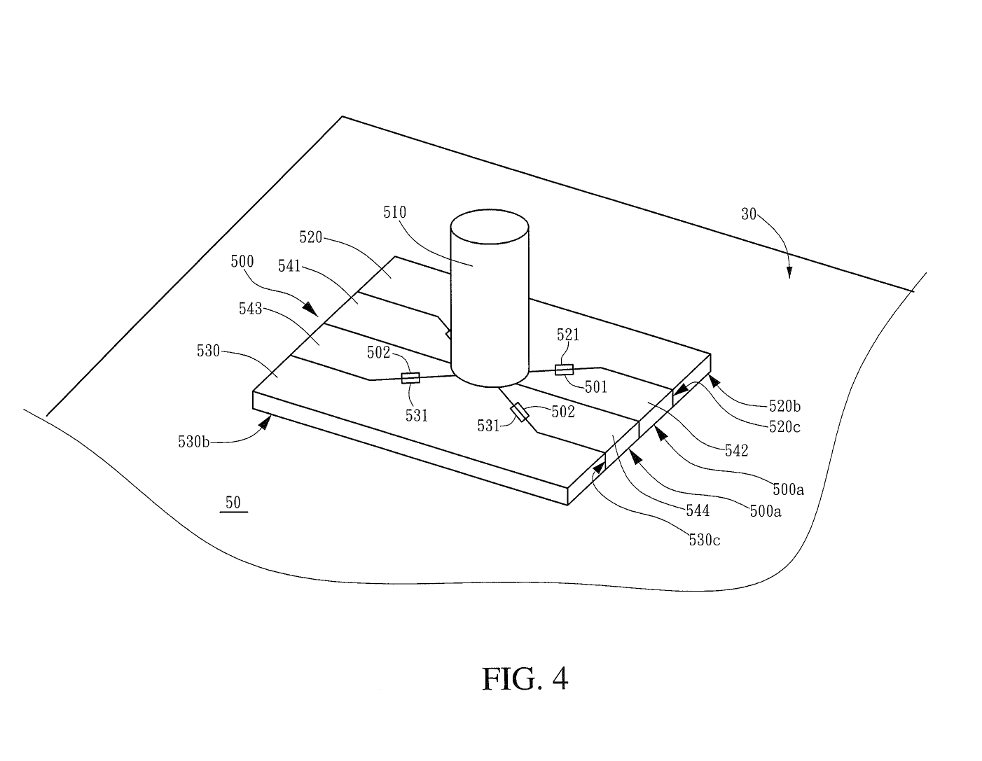

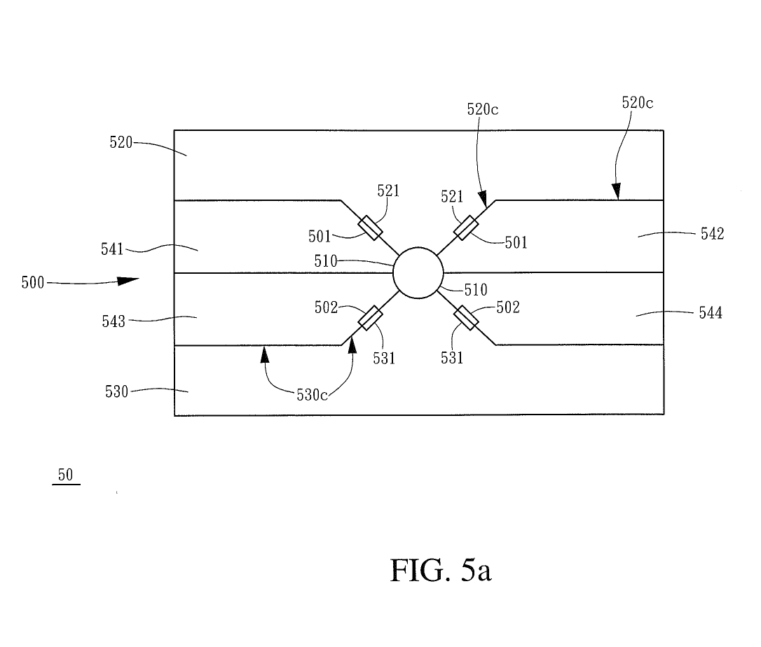

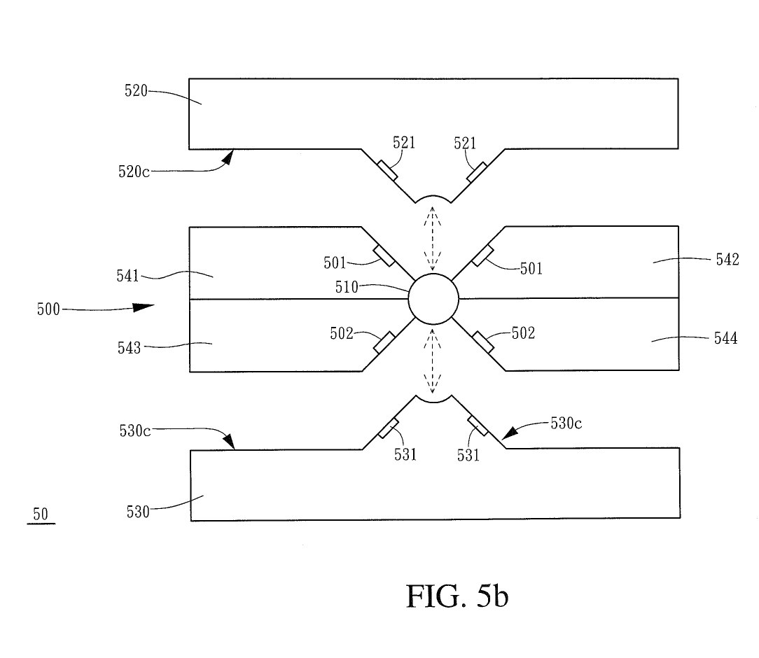

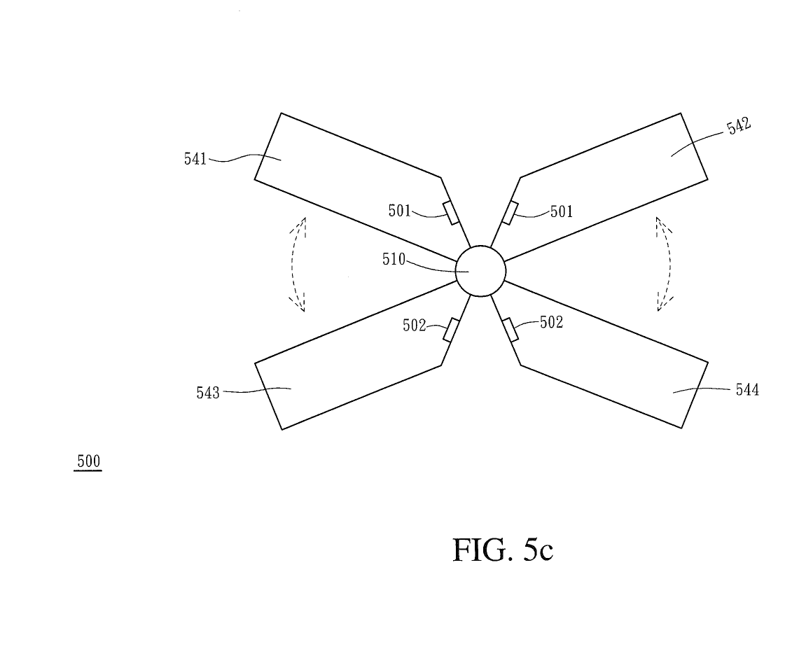

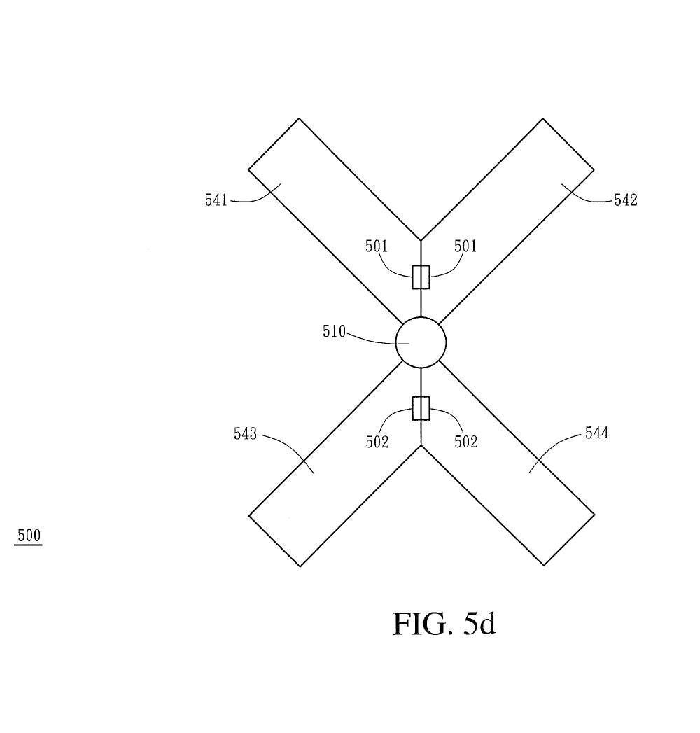

At the first aspect, the first wing 520 is integrated with the first base body 541 and the second base body 542. Moreover, the bottom face 520b of the first wing and the bottom surface 500a of the base body butt the bearing surface 30 simultaneously, as shown in FIGS. 4 and 5a. At the second aspect, the first wing 520 is detached from the first base body 541 and the second base body 542, as shown in FIGS. 3, 5b, 5c and 5d. Meanwhile, the first base body 541 and the second base body 542 are swivelable between a first position and a second position to adjust the angle between them as required. At the second position, the angle between the first base body 541 and the second base body 542 is 180 degrees, as shown in FIG. 5b. The first base body 541 and the second base body 542 could be close to each other by swivelling, as shown in FIG. 5c. When the first base body 541 and the second base body 542 are swivelled to the first position finally, the first connecting parts 501 located on the first base body 541 and the second base body 542 are coupled with each other, as shown in FIG. 5d.

The second wing 530 has a bottom face 530b and a side face 530c. The side face 530c has a fourth connecting part 531 located thereon detachably connected to the third connecting part 502 such that the second wing 530 can form a third aspect and a fourth aspect relative to the base body module 500.

At the third aspect, the second wing 530 is integrated with the third base body 543 and the fourth base body 544. Moreover, the bottom face 530b of the second wing and the bottom face 500a of the base body butt the bearing surface 30 simultaneously, as shown in FIGS. 4 and 5a. At the fourth aspect, the second wing 530 is detached from the third base body 543 and the fourth base body 544, as shown in FIGS. 3, 5b, 5c and 5d. Meanwhile, the third base body 543 and the fourth base body 544 are swivelable between a third position and a fourth position to adjust the angle between them as required. At the fourth position, the angle between the third base body 543 and the fourth base body 544 is 180 degrees, as shown in FIG. 5b. The third base body 543 and the fourth base body 544 could be close to each other by rotating, as shown in FIG. 5c. When the third base body 543 and the fourth base body 544 are swivelled to the third position finally, the third connecting parts 502 located on the third base body 543 and the fourth base body 544 are coupled with each other, as shown in FIG. 5d.

When the first base body 541 and the second base body 542 are positioned at the second position and the third base body 543 and the fourth base body 544 are positioned at the fourth position, the first base body 541 is adjacent to the third base body 543, and the second base body 542 is adjacent to the fourth base body 544.

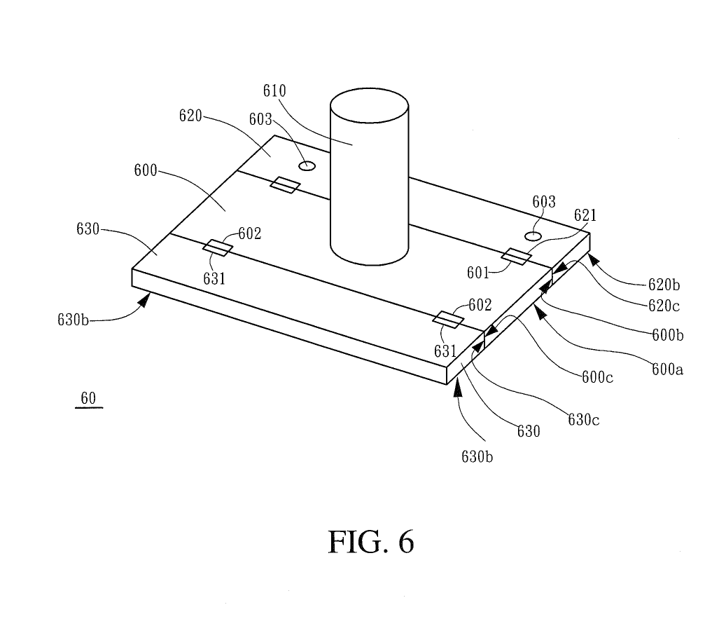

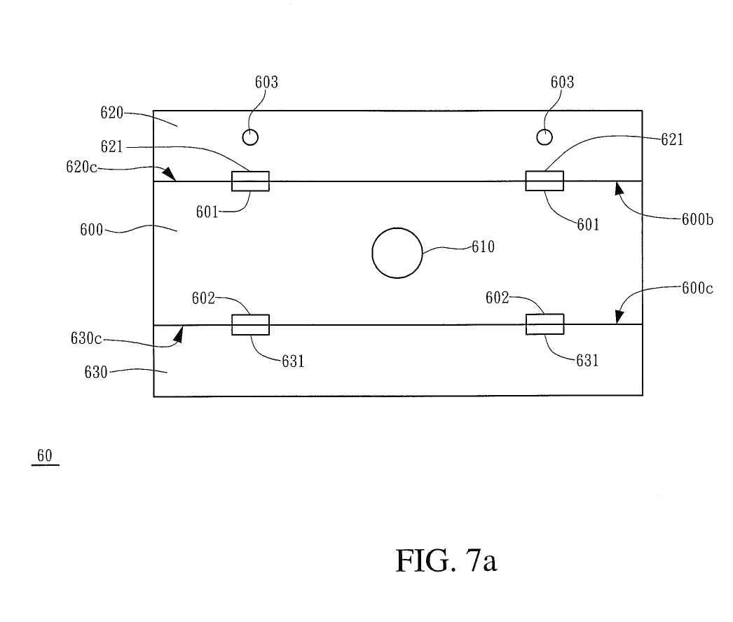

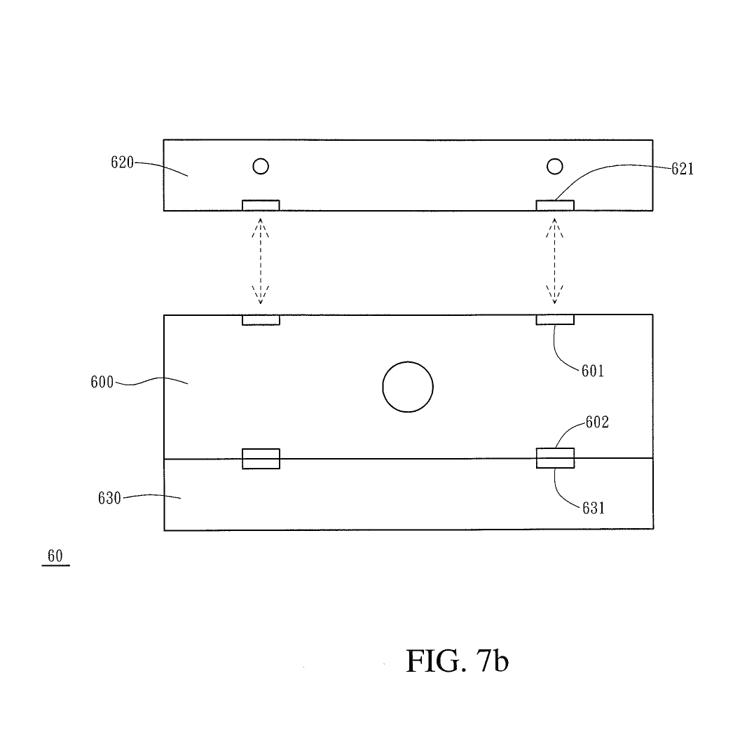

Please refer to FIGS. 6, 7a and 7b for a third embodiment of the invention. A base 60 includes a base body 600, a first wing 620, a second wing 630 and a pillar 610 to support the display device. The base body 600 has a first side face 600b with a first connecting part 601 located thereon detachably connected to a second connecting part 621 on a side face 620c of the first wing such that the first wing 620 can form a first aspect and a second aspect relative to the base body 600. At the first aspect, the first wing 620 is integrated with the base body 600. Moreover, a bottom face 620b of the first wing and a bottom face 600a of the base body butt the bearing surface simultaneously, as shown in FIGS. 6 and 7a. At the second aspect, the first wing 620 is detached from the base body 600, as shown in FIG. 7b.

The second side face 600c of the base body has a third connecting part 602 located thereon detachably connected to a fourth connecting part 631 on a side face 630c of the second wing such that the second wing 630 can form a third aspect and a fourth aspect relative to the base body 600. At the third aspect, the second wing 630 is integrated with the base body 600. Moreover, a bottom face 630b of the second wing and the bottom face 600a of the base body butt the bearing surface simultaneously. At the fourth aspect, the second wing 630 is detached from the base body 600.

In this embodiment, the first wing 620 has a through-hole 603. In other embodiments, the second wing could also have a through-hole; or no through-hole formed on the first wing and the second wing. In this embodiment, the first wing 620 and the second wing 630 are detachably connected to the base body 600. In other embodiments, the first wing could be hinged on the base body in a swivelable manner and the second wing can be detachably connected to the base body; alternatively, the first wing is detachably connected to the base body and the second wing is hinged on the base body in a swivelable manner.

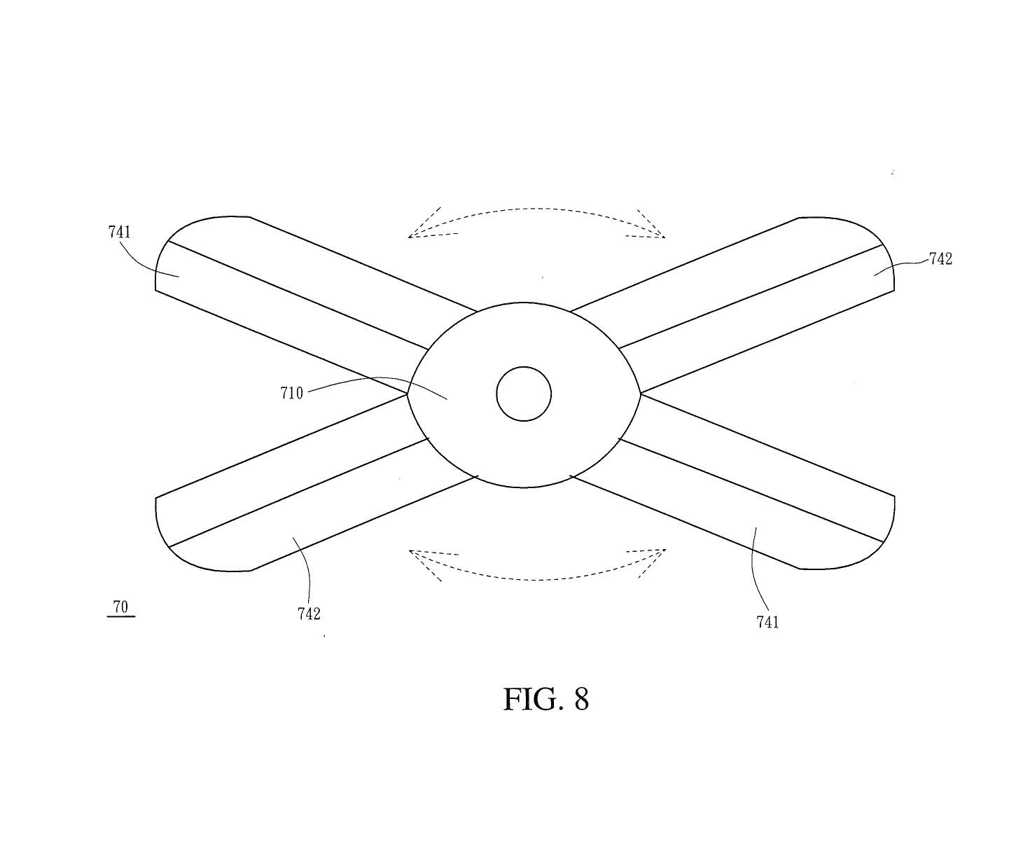

Please refer to FIG. 8 for a fourth embodiment of the invention. In this embodiment, a base 70 is formed without a first wing or a second wing, and includes only a first base body 741, a second base body 742 and a pillar 710. Moreover, the first base body 741 and the second base body 742 are intersecting with one another and hinged on the pillar 710 in a swivelable manner such that an angle between the first base body 741 and the second base body 742 is adjustable through the swivel movement about the pillar 710.

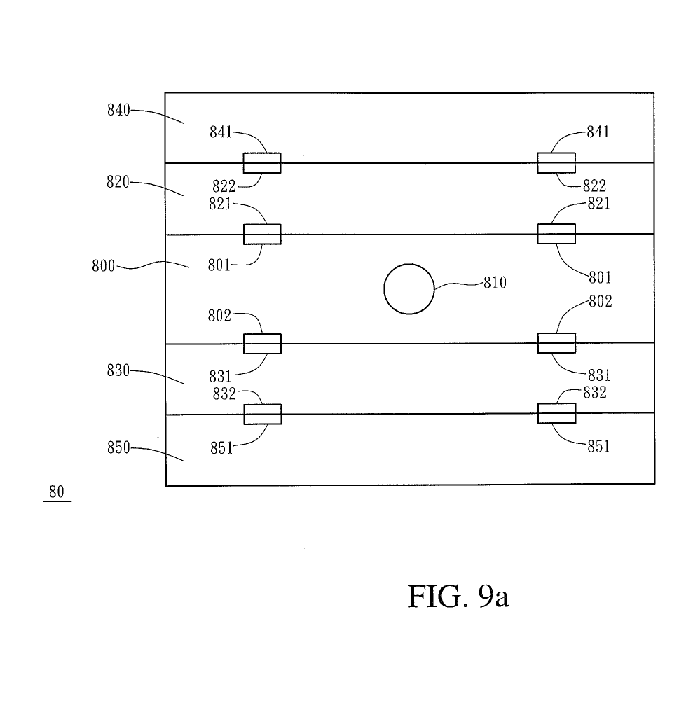

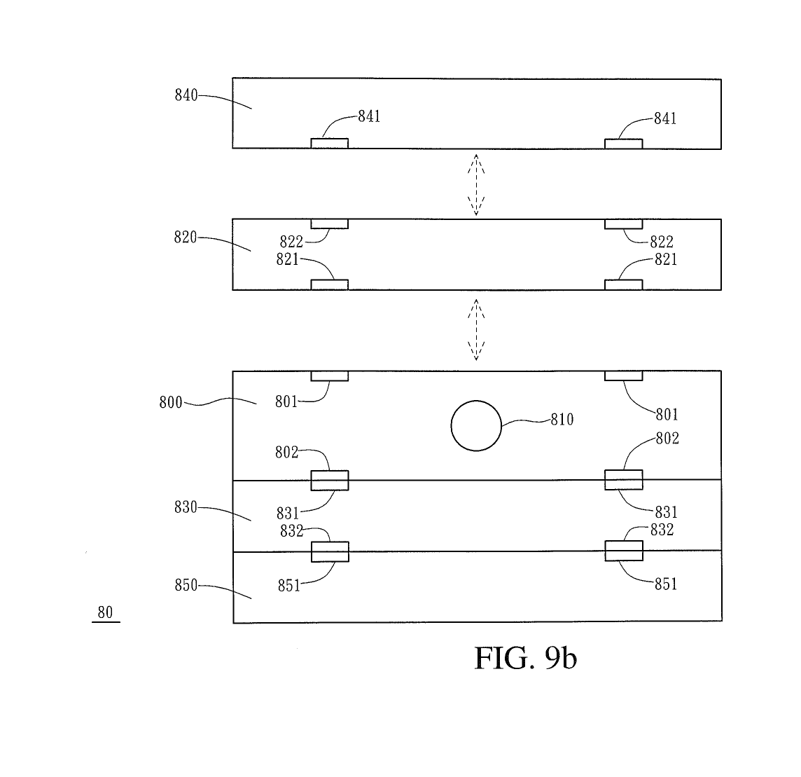

Please refer to FIGS. 9a and 9b for a fifth embodiment of the invention. In this embodiment, a base 80 is formed to include a first wing 820, a second wing 830, a third wing 840 and a fourth wing 850, as shown in FIG. 9a. The first wing 820 has a second connecting part 821 on one side detachably connected to a first connecting part 801 located at one side of a base body 800. The second wing 830 has a fourth connecting part 831 on one side detachably connected to a third connecting part 802 located at another side of the base body 800. The third wing 840 has a sixth connecting part 841 detachably connected to a fifth connecting part 822 located at another side of the first wing 820. The fourth wing 850 has an eighth connecting part 851 detachably connected to a seventh connecting part 832 located at another side of the second wing 830. In other words, the first wing 820, the second wing 830, the third wing 840 and the fourth wing 850 could be connected to or detached from one another in a fashion of multi-segment as required, as shown in FIG. 9b. In other embodiments, the base could contain even more wings to be adjusted in a fine-tuned and multi-stage manner as desired; alternatively, the detachable connecting part could be replaced by a swivelable one.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

I claim:

1. A base of a display device to be rested on a bearing surface to support the display device, comprising:
a base body including a pillar, a bottom face butting the bearing surface and a first side face and a second side face opposite to each other and adjacent to the bottom face, the pillar having a top end connecting to the display device to support the display device, the first side face having a first connecting part located thereon;
a first wing including a bottom face and a side face thereof, the side face having a second connecting part corresponding to the first connecting part; wherein: the first connecting part is hinged on the second connecting part in a swivelable manner such that the first wing is swivelable between a first position and a second position relative to the base body; when the first wing is swivelled to the first position the bottom face of the first wing is substantially perpendicular to the bearing surface, when the first wing is swivelled to the second position the bottom face of the first wing and the bottom face of the base body butt the bearing surface simultaneously; and
a second wing connected to the second side face of the base body.

2. The base of the display device according to claim 1, wherein the first wing and the second wing are formed in symmetrical shapes and sizes.

3. The base of the display device according to claim 1, wherein the second side face of the base body has a third connecting part, and the second wing has a bottom face and a side face thereof; the side face of the second wing having a fourth connecting part corresponding to the third connecting part; wherein: the third connecting part is hinged on the fourth connecting part in a swivelable manner such that the second wing is swivelable between a third position and a fourth position relative to the base body; when the second wing is swivelled to the third position the bottom face of the second wing is substantially perpendicular to the bearing surface; when the second wing is swivelled to the fourth position the bottom face of the second wing and the bottom face of the base body butt the bearing surface simultaneously.

4. The base of the display device according to claim 3, wherein the bottom face of the base body, the bottom face of the first wing and the bottom face of the second wing have respectively an anti-slip pad.

5. The base of the display device according to claim 1, wherein the first wing has a through-hole.

6. The base of the display device according to claim 3, wherein the second wing has a through-hole.

7. The base of the display device according to claim 5, wherein when the first wing is swivelled to the first position the first wing is fastenable to a wall via a coupling element passing through the through-hole.

8. The base of the display device according to claim 5, wherein when the first wing is swivelled to the second position the first wing is fastenable to the bearing surface via the coupling element passing through the through-hole.

9. The base of the display device according to claim 6, wherein when the second wing is swivelled to the third position the second wing is fastenable to a wall via a coupling element passing through the through-hole.

10. The base of the display device according to claim 6, wherein when the second wing is swivelled to the fourth position the second wing is fastenable to the bearing surface via the coupling element passing through the through-hole.

11. A base of a display device to be rested on a bearing surface to support the display device, comprising:
a base body including a pillar, a bottom face butting the bearing surface and a first side face and a second side face opposite to each other and adjacent to the bottom face, the pillar having a top end connecting to the display device to support the display device, the first side face having a first connecting part located thereon;
a first wing including a bottom face and a side face thereof, the side face having a second connecting part corresponding to the first connecting part; wherein: the first connecting part is detachably connected to the second connecting part such that the first wing is formed a first aspect and a second aspect relative to the base body; at the first aspect the first wing is integrated with the base body, and the bottom face of the first wing and the bottom face of the base body butt the bearing surface simultaneously; at the second aspect the first wing is detached from the base body; and
a second wing connected to the second side face of the base body.

12. The base of the display device according to claim 11, wherein the first wing and the second wing are formed in symmetrical shapes and sizes.

13. The base of the display device according to claim 11, wherein the second side face of the base body has a third connecting part, and the second wing has a bottom face and a side face thereof; the side face of the second wing having a fourth connecting part corresponding to the third connecting part; wherein: the third connecting part is detachably connected to the fourth connecting part such that the second wing forms a third aspect and a fourth aspect relative to the base body; at the third aspect the second wing is integrated with the base body, and the bottom face of the second wing and the bottom face of the base body butt the bearing surface simultaneously; at the fourth aspect, the second wing is detached from the base body.

14. The base of the display device according to claim 13, wherein the bottom face of the base body, the bottom face of the first wing and the bottom face of the second wing have respectively an anti-slip pad.

15. The base of the display device according to claim 11, wherein the first wing has a through-hole.

16. The base of the display device according to claim 11, wherein the second wing has a through-hole.

17. The base of the display device according to claim 15, wherein the first wing is fastenable to the bearing surface via the coupling element passing through the through-hole.

18. The base of the display device according to claim 16, wherein the second wing is fastenable to the bearing surface via the coupling element passing through the through-hole.

19. A base of a display device to be rested on a bearing surface to support the display device, comprising:
a base body module including a first base body, a second base body, a third base body, a fourth base body and a pillar, the first base body, the second base body, the third base body and the fourth base body being hinged respectively on the pillar in a swivelable manner and each base body having a bottom face butting the bearing surface, the pillar having a top end connecting to the display device to support the display device;
a first wing having a bottom face and a side face, the first base body and the second base body having respectively a side face thereof to hold a first connecting part, the first wing having a side face thereof to hold a second connecting part corresponding to the first connecting part, the first connecting part being detachably connected to the second connecting part such that the first wing forms a first aspect and a second aspect relative to the base body module; at the first aspect the first wing being integrated with the first base body and the second base body, and the bottom face of the first wing and the bottom face of the base body butting the bearing surface simultaneously; at the second aspect the first wing being detached from the first base body and the second base body; and
a second wing having a bottom face and a side face thereof, the third base body and the fourth base body having respectively a side face thereof to hold a third connecting part, the second wing having a side face thereof to hold a fourth connecting part corresponding to the third connecting part; the third connecting part being detachably connected to the fourth connecting part such that the second wing forms a third aspect and a fourth aspect relative to the base body module; at the third aspect the second wing being integrated with the third base body and the fourth base body, and the bottom face of the second wing and the bottom face of the base body butting the bearing surface simultaneously; at the fourth aspect the second wing being detached from the third base body and the fourth base body.

20. The base of the display device according to claim 19, wherein at the second aspect the first base body and the second base body are swivelable between a first position and a second position, the first base body and the second base body being adjacent to each other at the first position, and the first connecting parts on the first base body and the second base body being coupled with each other; at the fourth aspect the third base body and the fourth base body being swivelable between a third position and a fourth position, the third base body and the fourth base body being adjacent to each other at the third position, and the third connecting parts on the third base body and the fourth base body being coupled with each other; when the first base body and the second base body are positioned at the second position and the third base body and the fourth base body are positioned at the fourth position, the first base body is adjacent to the third base body and the second base body is adjacent to the fourth base body.
